(19) United States
(12) Patent Application Publication
(10) Pub. No.: US 2011/0219288 A1
(43) Pub. Date: Sep. 8, 2011

(54) METHOD OF OPERATING NONVOLATILE MEMORY DEVICE, METHOD OF OPERATING CONTROLLER, AND METHOD OF OPERATING MEMORY SYSTEM INCLUDING THE SAME

(75) Inventors: Yong June KIM, Seoul (KR); Jaehong Kim, Seoul (KR); Hong Rak Son, Anyang-si (KR); Jun Jin Kong, Yongin-si (KR)

(73) Assignee: Samsung Electronics Co., Ltd, Suwon-si (KR)

(21) Appl. No.: 13/040,807

(22) Filed: Mar. 4, 2011

(30) Foreign Application Priority Data
Mar. 5, 2010 (KR) 10-2010-0019730

(51) Int. Cl. H03M 13/09; G06F 11/10

(52) U.S. Cl. 714/805; 714/E11.034

(57) ABSTRACT

An method of operating a memory system including a nonvolatile memory device and a controller. The method includes receiving a source word, converting the received source word to a codeword, and programming the converted codeword in the nonvolatile memory device. A length of the converted codeword can be greater than a length of the received source word, and a difference between the numbers of first and second digital bits of the converted codeword can be less than a reference value.

### CROSS-REFERENCE TO RELATED APPLICATIONS

This U.S. non-provisional patent application claims priority under 35 U.S.C. §119 of Korean Patent Application No. 10-2010-0019730, filed on Mar. 5, 2010, the entire contents of which are hereby incorporated by reference.

### BACKGROUND

1. Field of the Invention

The present general inventive concept relates to a semiconductor memory, and more particularly, to an operating method of nonvolatile memory device, an operating method of controller, and an operating method of memory system including the same.

2. Description of the Related Art

A semiconductor memory device is a memory device that is implemented with semiconductor materials such as silicon (Si), germanium (Ge), gallium arsenide (GaAs) and indium phosphide (InP). Semiconductor memory devices are largely divided into volatile memory devices and nonvolatile memory devices.

The volatile memory device is a memory device in which stored data are erased when a power source is shut off. Volatile memory devices are Static Random Access Memory (SRAM), Dynamic Random Access Memory (DRAM) and Synchronous Dynamic Random Access Memory (SDRAM). The volatile memory device is a memory device that retains stored data even when a power source is shut off. Nonvolatile memory devices are Read-Only Memory (ROM), Programmable Read Only Memory (PROM), Erasable Programmable Read Only Memory (EPROM), Electrical Erasable Programmable Read Only Memory (EEPROM), flash memory device, Phase-change Random Access Memory (PRAM), Magnetoresistive Random Access Memory (MRAM), Resistive Random Access Memory (RRAM) and Ferroelectric Random Access Memory (FRAM). The flash memory device is largely categorized into a NOR type and a NAND type.

### SUMMARY

The present general inventive concept provides an operating method of nonvolatile memory device, an operating method of controller, and an operating method of memory system including the same.

Additional features and utilities of the present general inventive concept will be set forth in part in the description which follows and, in part, will be obvious from the description, or may be learned by practice of the present general inventive concept.

Exemplary embodiments of the inventive concept can provide a method of operating a memory system having a nonvolatile memory device and a controller, including receiving a source word, converting the received source word to a codeword, and programming the converted codeword in the nonvolatile memory device, where a length of the converted codeword is greater than a length of the received source word, and a difference between the numbers of first and second digital bits of the converted codeword is less than a reference value.

In exemplary embodiments of the present general inventive concept, the numbers of first and second digital bits of the converted codeword may have predetermined values in the converting of the received source word.

In exemplary embodiments of the present general inventive concept, the converting the received source word may include calculating a difference between the numbers of first and second digital bits of the received source word, generating a balance parity based on the calculated difference, and selecting the received source word and the balance parity as the converted codeword.

In exemplary embodiments of the present general inventive concept, the balance parity may compensate the difference between the number of first digital bits and the number of second digital bits.

In exemplary embodiments of the present general inventive concept, the operating method may include reading the programmed codeword in a reading operation, and removing the balance parity of the read codeword to acquire the source word from the read codeword.

In exemplary embodiments of the present general inventive concept, the converting the received source word may include selecting a codeword corresponding to the received source word, based on a specific replacing table which comprises a group of source words and a group of codewords.

In exemplary embodiments of the present general inventive concept, the numbers of first and second digital bits of each of the codewords may have predetermined values.

In exemplary embodiments of the present general inventive concept, the operating method may include reading the programmed codeword in a reading operation, and selecting a source word corresponding to the read codeword based on the replacing table.

In exemplary embodiments of the present general inventive concept, the operating method may include calculating a sum of differences between the numbers of first and second digital bits of codewords which are pre-programmed before the programming of the converted codeword.

In exemplary embodiments of the present general inventive concept, the converting the received source word may include selecting first and second encoded words corresponding to the received source word, based on a replacing table comprising a group of source words, a group of first encoded words, and a group of second encoded words, calculating a difference between the numbers of first and second digital bits of the selected first encoded words, and a difference between the numbers of first and second digital bits of the selected second encoded words, and selecting one of the selected first and second encoded words as a codeword, based on the sum of differences between the numbers of first and second digital bits of the pre-programmed codewords, the difference between the numbers of first and second digital bits of the selected first encoded words, and the difference between the numbers of first and second digital bits of the selected second encoded words.

In exemplary embodiments of the present general inventive concept, the difference between the numbers of first and second digital bits of the selected first encoded words and the difference between the numbers of first and second digital bits of the selected second encoded words may have the same size and different signs.

In exemplary embodiments of the present general inventive concept, the selecting of one of the selected first and second encoded words as a codeword may include decreasing an absolute value of a sum of differences between the numbers of first and second digital bits of the pre-programmed codewords among the first and second encoded words.

In exemplary embodiments of the present general inventive concept, the operating method may include reading the programmed codeword in a reading operation, and selecting a source word corresponding to the read codeword based on the replacing table.

In exemplary embodiments of the present general inventive concept, the converting the received source word may include generating an inverted word of the received source word, respectively inserting polarity bits into the received source word and the inverted word to polarize the words, calculating a difference between the numbers of first and second digital bits of the polarized source word and a difference between the numbers of first and second digital bits of the polarized inverted word, and selecting one of the polarized source word and the polarized inverted word as a codeword, based on the sum of differences between the numbers of first and second digital bits of the pre-programmed codewords, the difference between the numbers of first and second digital bits of the polarized source word, and the difference between the numbers of first and second digital bits of the polarized inverted word.

In exemplary embodiments of the present general inventive concept, the operating method may include reading the programmed codeword in a reading operation, detecting a polarity bit from the read codeword, removing the polarity bit from the read codeword, and selecting whether to invert a codeword from which the polarity bit is removed based on the detected polarity bit.

In exemplary embodiments of the present general inventive concept, the converting the received source word may include inserting different J-bit index bits into the received source word to generate a J number of index words, scrambling the J index words to generate a J number of scrambled words, calculating a difference between the numbers of first and second digital bits of each of the J scrambled words, and selecting one of the J scrambled words as a codeword, based on the sum of differences between the numbers of first and second digital bits of the pre-programmed codewords and the difference between the numbers of first and second digital bits of each of the J scrambled words.

In exemplary embodiments of the present general inventive concept, the generating of a J number of scrambled words may include multiplicative scrambling the J scrambled index words.

In exemplary embodiments of the present general inventive concept, the operating method may include reading the programmed codeword in a reading operation, descrambling the read codeword, and removing an index bit from the descrambled codeword.

In exemplary embodiments of the present general inventive concept, a method of operating a controller to control a nonvolatile memory device in a memory system includes receiving a source word, converting the received source word to a codeword, and outputting the converted codeword to the nonvolatile memory device, where a length of the converted codeword is greater than a length of the received source word, and a difference between the numbers of first and second digital bits of the converted codeword is less than a reference value.

In exemplary embodiments of the present general inventive concept, a method of operating a nonvolatile memory device in a memory system includes receiving a source word, converting the received source word to a codeword, and programming the converted codeword, where a length of the converted codeword is greater than a length of the received source word, and a difference between the numbers of first and second digital bits of the converted codeword is less than a reference value.

Exemplary embodiments of the present general inventive concept also provide a method of operating a memory system including a nonvolatile memory device and a controller, the method including receiving a source word, converting the received source word to a codeword, outputting the converted codeword to the nonvolatile memory device, and programming the outputted converted codeword in the nonvolatile memory device, where a length of the converted codeword is greater than a length of the received source word, and a difference between the numbers of first and second digital bits of the converted codeword is less than a reference value.

The converting of the method may include converting the received source word to the codeword with a disparity controller.

The method may include calculating a disparity of the received source word with the controller, and generating a balance parity according to at least the calculated disparity with the controller, where the outputting the codeword includes outputting the received source word with the generated balance parity.

The calculating the disparity may include calculating a difference between the numbers of first and second bits of the received source word.

The method may include where the outputted codeword has a zero disparity.

The converting of the method may include selecting a codeword according to a received source word and a replacing table with the controller.

Exemplary embodiments of the present general inventive concept may also provide a memory system including a nonvolatile memory device, a disparity controller communicatively coupled to the nonvolatile memory device to receiving a source word, convert the received source word to a codeword, output the converted codeword to the nonvolatile memory device, and program the outputted converted codeword in the nonvolatile memory device, where a length of the converted codeword is greater than a length of the received source word, and a difference between the numbers of first and second digital bits of the converted codeword is less than a reference value.

### BRIEF DESCRIPTION OF THE DRAWINGS

The above and/or other features and utilities of the present general inventive concept will become apparent and more readily appreciated from the following description of the exemplary embodiments, taken in conjunction with the accompanying drawings, in which:

FIG. 1 is a block diagram illustrating a memory system according to exemplary embodiments of the present general inventive concept;

FIG. 2 is a block diagram illustrating a nonvolatile memory device included in the memory system of FIG. 1 according to exemplary embodiments of the present general inventive concept;

FIG. 3 is a flowchart illustrating an operation of a disparity control unit of FIG. 1 according to exemplary embodiments of the present general inventive concept;

FIG. 4 is a block diagram illustrating a disparity control unit according to exemplary embodiments of the present general inventive concept;

FIG. 5 is a flowchart illustrating an operation of the disparity control unit of FIG. 4 according to exemplary embodiments of the present general inventive concept;

FIG. 6 is a flowchart illustrating an operation of the disparity control unit of FIG. 4 in a reading operation of a nonvolatile memory device according to exemplary embodiments of the present general inventive concept;

FIG. 7 is a graph illustrating the probability that a zero disparity may fail based on the number of bits of codewords and a balance parity according to exemplary embodiments of the present general inventive concept;

FIG. 8 is a block diagram illustrating a disparity control unit according to exemplary embodiments of the present general inventive concept;

FIG. 9 is a flowchart illustrating an operation of a disparity control unit of FIG. 8 according to exemplary embodiments of the present general inventive concept;

FIG. 10 is a flowchart illustrating an operation of the disparity control unit of FIG. 8 in a reading operation of a nonvolatile memory device 100 according to exemplary embodiments of the present general inventive concept;

FIG. 11 is a block diagram illustrating a disparity control unit according to exemplary embodiments of the present general inventive concept;

FIG. 12 is a flowchart illustrating an operation of the disparity control unit of FIG. 11;

FIG. 13 is a flowchart illustrating an operation of the disparity control unit of FIG. 11 in a reading operation of a nonvolatile memory device according to exemplary embodiments of the present general inventive concept;

FIG. 14A is a block diagram illustrating a disparity control unit including a reading unit and a writing unit according to exemplary embodiments of the present general inventive concept;

FIG. 14B is a block diagram illustrating a writing unit of a disparity control unit according to exemplary embodiments of the present general inventive concept;

FIG. 15 is a flowchart illustrating an operation of the writing unit of FIG. 14B according to exemplary embodiments of the present general inventive concept;

FIG. 16 is a block diagram illustrating a reading unit of a disparity control unit according to exemplary embodiments of the present general inventive concept;

FIG. 17 is a flowchart illustrating an operation of the reading unit of FIG. 16 according to exemplary embodiments of the present general inventive concept;

FIG. 18 is a block diagram illustrating a reading unit of a disparity control unit according to exemplary embodiments of the present general inventive concept;

FIG. 19 is a flowchart illustrating an operation of the reading unit of FIG. 18 according to exemplary embodiments of the present general inventive concept;

FIG. 20 is a block diagram illustrating a writing unit of a disparity control unit according to exemplary embodiments of the inventive concept;

FIG. 21 is a flowchart illustrating an operation of the writing unit of FIG. 20 according to exemplary embodiments of the present general inventive concept;

FIG. 22 is a block diagram illustrating a reading unit of a disparity control unit according to exemplary embodiments of the present general inventive concept;

FIG. 23 is a flowchart illustrating an operation of the reading unit of FIG. 22 according to exemplary embodiments of the present general inventive concept;

FIG. 24 is a block diagram illustrating a first application example of the memory system of FIG. 1 according to exemplary embodiments of the present general inventive concept;

FIG. 25 is a block diagram illustrating a second application example of the memory system of FIG. 1 according to exemplary embodiments of the present general inventive concept;

FIG. 26 is a block diagram illustrating a memory system according to exemplary embodiments of the present general inventive concept;

FIG. 27 is a block diagram illustrating a memory system according to exemplary embodiments of the present general inventive concept; and

FIG. 28 is a block diagram illustrating a computing system which includes the memory system of FIG. 27 according to exemplary embodiments of the present general inventive concept.

### DETAILED DESCRIPTION OF THE EMBODIMENTS

Exemplary embodiments of the inventive concept will be described below in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. Like reference numerals refer to like elements throughout. Similar reference numerals refer to similar elements throughout.

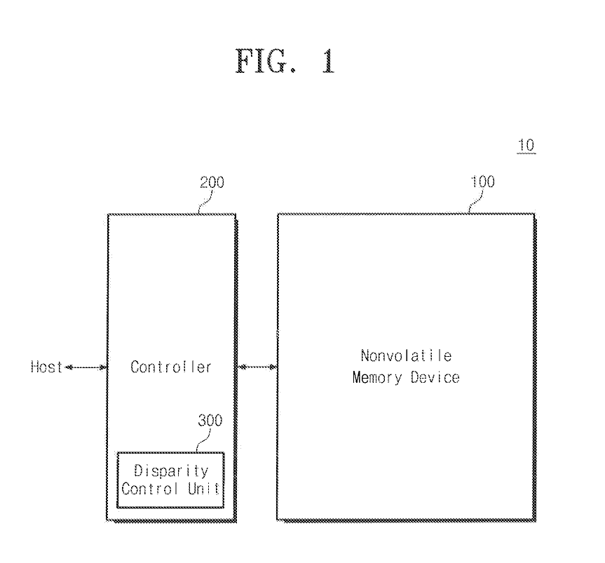

FIG. 1 is a block diagram illustrating a memory system 10 according to exemplary embodiments of the present general inventive concept.

Referring to FIG. 1, the memory system 10 according to exemplary embodiments of the present general inventive concept can include a nonvolatile memory device 100 and a controller 200, which can be formed as two separate elements communicatively coupled to one another through one or more data lines to transmit data, or as a single monolithic body. The memory system 10 may include at least one of the nonvolatile memory device 100 and the controller 200 to perform the operations of the memory system 10 as disclosed herein in exemplary embodiments of the present general inventive concept.

The nonvolatile memory device 100 can be a ROM, PROM, EPROM, EEPROM, flash memory device, PRAM, MRAM, RRAM, or FRAM, or any other suitable nonvolatile memory device to carry out the exemplary embodiments of the present general inventive concept as disclosed herein. The controller 200 can be a processor, a field programmable gate array, a programmable logic device, and/or any other suitable controller to carry out the exemplary embodiments of the present general inventive concept.

The controller 200 can be communicatively connected to a host and a nonvolatile memory device 100. The controller 200 can be wirelessly connected and/or connected via a wired connection to the host and/or the nonvolatile memory device 100. According to a request from the host, the controller 200 can access the nonvolatile memory device 100. For example, the controller 200 can control the reading, writing, erasing, and background operations (e.g., supplying power and/or refreshing the memory, etc.) of the nonvolatile memory device 100. The controller 200 can provide an interface between the nonvolatile memory device 100 and the host. As an example, the controller 200 can drive a firmware for controlling the nonvolatile memory device 100.

The controller 200 can receive data in source word units from the host, where the units of the source word may be of a predetermined length or size. For example, the source word may be a sector or a cluster. The controller 200 can convert the received source words to codewords, respectively. The controller 200 can transmit the converted codewords to the nonvolatile memory device 100. The controller 200 can control the nonvolatile memory device 100 in order for the transmitted codewords to be programmed (e.g., programmed into the nonvolatile memory device 100).

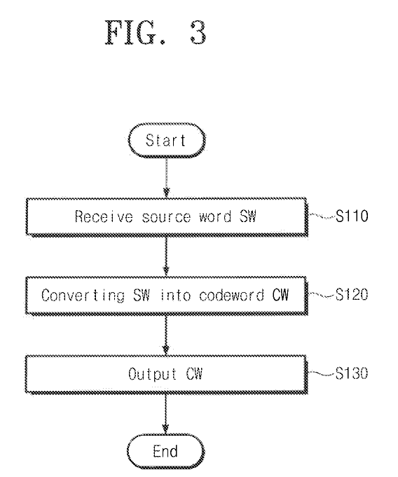

The controller 200 can include a disparity control unit 300. The disparity control unit 300 can convert a source word, which is received from the host, to a codeword. The disparity control unit 300 will be described below in more detail with reference to FIGS. 3 to 21.

Exemplarily, the controller 200 may include elements such as a RAM (Random Access Memory), a processing unit, a host interface and a memory interface. The RAM can be used as at least one of a cache memory between the nonvolatile memory device 100 and the host, and a buffer memory between the nonvolatile memory device 100 and the host. The processing unit can control the operation of the controller 200.

A host interface can include a protocol to perform data exchange between the host and the controller 200. Exemplarily, the controller 200 can communicate with the outside (for example, the host) through at least one of various interface protocols such as a Universal Serial Bus (USB) protocol, a Multimedia Card (MMC) protocol, a Peripheral Component Interconnection (PCI) protocol, a PCI-Express (PCI-E) protocol, an Advanced Technology Attachment (ATA) protocol, a Serial-ATA (SATA) protocol, a Parallel-ATA (PATA) protocol, a Small Component Small Interface (SCSI) protocol, an Enhanced Small Disk Interface (ESDI) protocol and a Integrated Drive Electronics (IDE) protocol.

A memory interface can interface with the nonvolatile memory device 100. For example, the memory interface can include a NAND interface or a NOR interface.

The memory system 10 may include an error correction block. The error correction block may include one or more logic circuits to perform error correction. The error correction block can detect and correct the error of data that is read from the nonvolatile memory device 100 by an Error Correction Code (ECC). Exemplarily, the error correction block can be provided by the controller 200. The error correction block may be provided by the nonvolatile memory device 100.

The controller 200 and the nonvolatile memory device 100 may be integrated as one semiconductor device. Exemplarily, the controller 200 and the nonvolatile memory device 100 can be integrated as one semiconductor device to configure a memory card. For example, the controller 200 and the nonvolatile memory device 100 can be integrated as one semiconductor device to configure a memory card such as Personal Computer Memory Card International Association (PCMCIA), Compact Flash (CF), smart media card (SM, SMC), memory stick, multimedia card (MMC, RS-MMC, MMCmicro), SD card (SD, miniSD, microSD, microSD, SDHC) and universal flash memory device.

The controller 200 and the nonvolatile memory device 100 can be integrated as one semiconductor memory to configure a semiconductor drive (for example, Solid State Drive (SSD)). The semiconductor driver (SSD) can include a storage device that stores data in a semiconductor memory. When the memory system is used as the semiconductor drive (SSD), the operation speed of the host connected to the memory system 10 can be increased and/or improved.

As another example, the memory system 10 can be provided as one of various elements of electronic devices such as computers, Ultra Mobile PCs (UMPCs), workstations, net-books, Personal Digital Assistants (PDAs), portable computers, web tablets, wireless phones, mobile phones, smart phones, e-books, Portable Multimedia Players (PMPs), portable game machines, navigation devices, black boxes, digital cameras, Digital Multimedia Broadcasting (DMB) players, digital audio recorders, digital audio players, digital picture recorders, digital picture players, digital video recorders, digital video players, devices to transmit/receive information at a wireless environment, one of various electronic devices configuring a home network, one of various electronic devices configuring a computer network, one of various electronic devices configuring a telematics network, RFID (radio frequency identification) devices and one of various elements configuring a computing system.

Exemplarily, the nonvolatile memory device 100 or the memory system 10 according to exemplary embodiments of the present general inventive concept may be mounted as various types of packages. For example, the nonvolatile memory device 100 or the memory system 10 according to exemplary embodiments of the present general inventive concept may be packaged in a package type such as Package on Package (PoP), Ball Grid Arrays (BGAs), Chip Scale Packages (CSPs), Plastic Leaded Chip Carrier (PLCC), Plastic Dual In-Line Package (PDIP), Die In Waffle Pack (DIWP), Die In Wafer Form (DIWF), Chip On Board (COB), Ceramic Dual In-Line Package (CERDIP), Plastic Metric Quad Flat Pack (MQFP), Thin Quad Flat Pack (TQFP), Small Outline Package (SOP), Shrink Small Outline Package (SSOP), Thin Small Outline Package (TSOP), Thin Quad Flat Pack (TQFP), System In Package (SIP), Multi Chip Package (MCP), Wafer Level Stack Package (WLSP), Die In Wafer Form (DIWF), Die On Waffle Package (DOWP), Wafer-level Fabricated Package (WFP) and Wafer-Level Processed Stack Package (WSP), thereby being mounted.

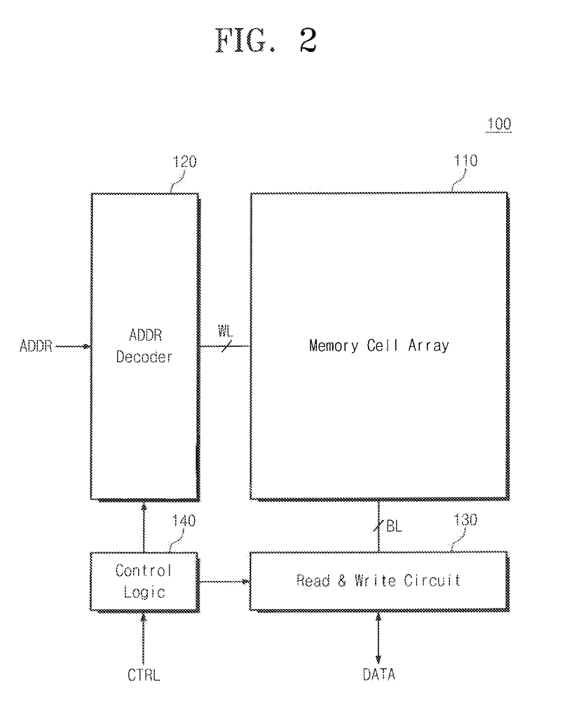

FIG. 2 is a block diagram illustrating the nonvolatile memory device 100 of FIG. 1.

Referring to FIG. 2, the nonvolatile memory device 100 can include a memory cell array 110, an address decoder 120, a reading and writing circuit 130, and a control logic 140.

The memory cell array 110 can be communicatively connected to the address decoder 120 through word lines WL and can be communicatively connected to the reading and writing circuit 130 through bit lines BL. The memory cell array 110 includes a plurality of memory cells. Exemplarily, memory cells can be arranged in the row direction can be connected to the word lines WL. Memory cells can be arranged in the column direction can be connected to the bit lines BL. Exemplarily, the memory cell array 110 may store one or more bits in each cell.

The address decoder 120 can be connected to the memory cell array 110 through the word lines WL. The address decoder 120 may include one or more logic circuits to decode a received memory address. The address decoder 120 can operate according to the control of the control logic 150. The address decoder 120 can receive an address ADDR from the outside (e.g., a host that is communicatively coupled to the non-volatile memory device 100 and/or the controller 200 illustrated in FIG. 1). For example, the address decoder 120 can receive the address ADDR from the controller 200 of FIG. 1.

The address decoder 120 can decode the row address of the received address ADDR. The address decoder 120 can select the word lines WL by using the decoded row address. The address decoder 120 can decode the column address of the received address ADDR. The decoded column address can be transferred to the reading and writing circuit 130. Exemplarily, the address decoder 120 can include a row decoder, a column decoder, and an address buffer.

The reading and writing circuit 130 can be connected to the memory cell array 110 through the bit lines BL. The reading and writing circuit 130 can exchange data with the controller 200 of FIG. 1. The reading and writing circuit 130 can operate according to the control of the control logic 150. The reading and writing circuit 130 can receive the decoded column address from the address decoder 120. The reading and writing circuit 130 can select the bit lines BL by using the decoded column address.

Exemplarily, the reading and writing circuit 130 can receive data DATA from the outside (e.g., a host that is communicatively coupled to the non-volatile memory device 100 and/or the controller 200 illustrated in FIG. 1) and can write the received data DATA in the memory cell array 110. The reading and writing circuit 130 can read the data DATA from the memory cell array 110 and can output the read data DATA to the outside. The reading and writing circuit 130 can read data from a first storage region of the memory cell array 110 and can write the read data in a second storage region of the memory cell array 110. For example, the reading and writing circuit 230 can perform a copy-back operation.

As an example, the reading and writing circuit 130 can include a page buffer (or a page register), a column selection circuit, and a data buffer. As another example, the reading and writing circuit 130 can include a sensing amplifier, a writing driver, a column selection circuit, and a data buffer.

The control logic 140 can be connected to the address decoder 120 and the reading and writing circuit 130. The control logic 140 can control the operation of the flash memory device 100. The control logic 140 can operate in response to a control signal CTRL transferred from the outside (e.g., a host that is communicatively coupled to the non-volatile memory device 100 and/or the controller 200 illustrated in FIG. 1). For example, the control logic 140 can receive the control signal CTRL from the controller 200 of FIG. 1.

FIG. 3 is a flowchart illustrating an operation of the disparity control unit 300 of FIG. 1. A disparity may be a difference between the number of first digital bits (for example, 0 or 1) of a digital word and the number of second digital bits (for example, 1 or 0) of the digital word.

The disparity control unit 300 can receive a source word SW in operation S110. For example, the source word SW can be received from the host of FIG. 1.

The disparity control unit 300 can convert the source word SW to a codeword CW in operation S120. For example, the disparity control unit 300 can insert one or more additional bits into the source word SW from the host. Based on the one or more additional bits, the disparity control unit 300 can convert the received source word SW to the codeword CW.

For example, a difference between the number of first digital bits of codeword CW and the number of second digital bits of codeword CW (i.e., a disparity) can be controlled to less than a reference value according to the control of the disparity control unit 300. That is, the numbers of first and second digital bits of the codeword CW can be standardized (e.g., set to predetermined values) according to the control of the disparity control unit 300.

For example, the disparity control unit 300 can sum the disparities of codewords CW that are transmitted to the nonvolatile memory device 100 to calculate a Running Digital Sum (RDL). The disparity control unit 300 can control the codeword CW in order for the RDL of the codewords CW to be controlled to less than the reference value. For example, the disparity control unit 300 can control the codeword CW in order for the RDL of the codewords CW to be controlled to 0. That is, the numbers of first and second digital bits of the codewords CW are standardized (e.g., can be set to predetermined values) according to the control of the disparity control unit 300.

The disparity control unit 300 can output the converted codeword CW in operation S130. The codeword CW can be transmitted to the nonvolatile memory device 100 according to the control of the controller 200. The transmitted codeword CW can be programmed in the nonvolatile memory device 100.

As an example, based on the codewords CW programmed in the nonvolatile memory device 100, the read voltage level of the nonvolatile memory device 100 can be selected (e.g., by the control logic 140 illustrated in FIG. 2). When the numbers of first and second digital bits of the codewords CW programmed in the nonvolatile memory device 100 are standardized, a read error by the selected read voltage level can decrease and/or be minimized. That is, reliabilities for the nonvolatile memory device 100, the controller 200 and the memory system 10 can be improved and/or increased.

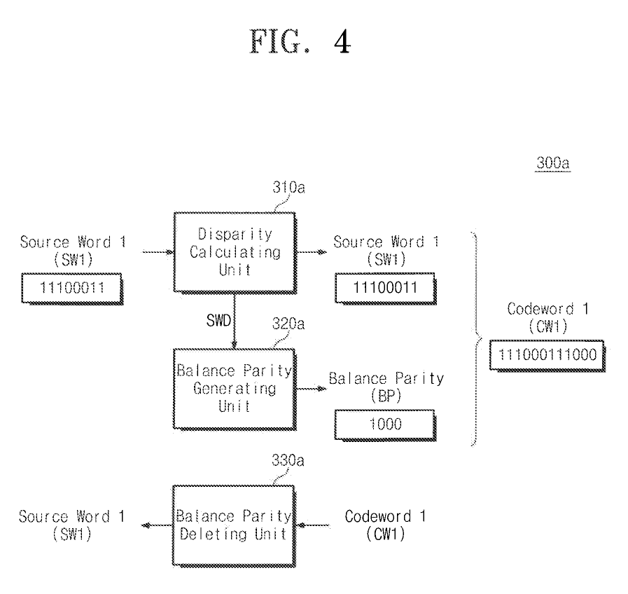

FIG. 4 is a block diagram illustrating a disparity control unit according to exemplary embodiments of the present general inventive concept.

Referring to FIG. 4, a disparity control unit 300a according to exemplary embodiments of the present general inventive concept can include a disparity calculating unit 310a, a balance parity generating unit 320a, and a balance parity deleting unit 330a.

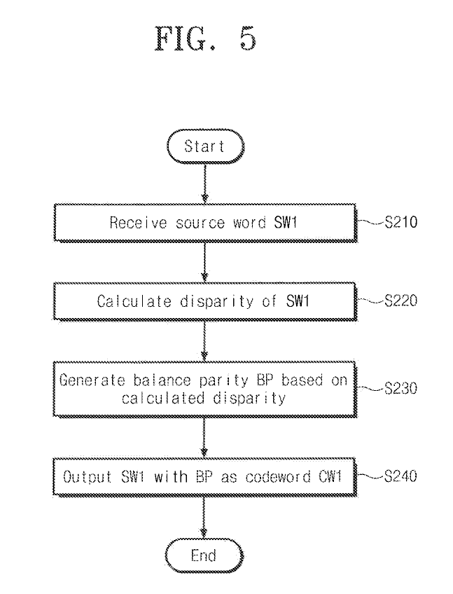

FIG. 5 is a flowchart illustrating an operation of the disparity control unit 300a of FIG. 4 according to exemplary embodiments of the present general inventive concept.

Referring to FIGS. 4 and 5, the disparity calculating unit 310a can receive a source word SW1 in operation S210. The disparity calculating unit 310a can calculate a disparity SWD of the received source word SW1 in operation S220. That is, the disparity calculating unit 310a can calculate a difference between the numbers of first and second digital bits of the received source word SW1. The calculated source word parity SWD can be transferred to the balance parity generating unit 320a. The disparity calculating unit 310a can output the source word SW1.

As an example, the source word SW is illustrated as ‘11100011’. In this case, a disparity of the source word SW1 may be calculated as 2. For example, the disparity is a value of 0 subtracted from 1.

The balance parity generating unit 320a can generate a balance parity BP based on the calculated source word SWD in operation S230. For example, a disparity of the balance parity BP can have the same size as that of the disparity of the source word SW1 and a sign opposite to that of the disparity of the source word SW1. For example, when the disparity of the source word SW1 is 2, the disparity of the balance parity BP is −2. As an example, the balance parity BP is illustrated as ‘1000’.

The source word SW and the balance parity BP can be output as the codeword CW1 in operation S240. When the disparity of the source word SW1 is 2 and the disparity of the balance parity BP is −2, the disparity of the codeword CW1 is 0. That is, the disparity control unit 300a outputs the codeword CW1 having a standardized number (e.g., a predetermined number) of first and second digital bits. For example, the codeword CW1 is illustrated as ‘111000111000’. That is, the codeword CW1 includes the source word SW1 ‘1110011’ and the balance parity BP ‘1000.’

As described above, the disparity control unit 300a can receive the source word SW1 and can output the codeword CW1 having a zero disparity. Therefore, codewords CW1 programmed in the nonvolatile memory device 100 can have a zero disparity.

For example, the number of bits of the balance parity BP may be specific. When the disparity of the source word SW1 is greater than the number of bits of the balance parity BP, the codeword CW1 may not be controlled to have a zero disparity. The disparity control unit 300a may set a balance mark indicating that the balancing of the codeword CW1 has failed (i.e., there is not a zero disparity).

For example, the disparity control unit 300a may output a codeword CW1 having a disparity equal to or less than a reference value. As an example, the disparity control unit 300a may output a codeword CW1 having a disparity equal to or less than ‘q’. That is, when the absolute value of the disparity of the codeword CW1 is less than ‘q’, the disparity control unit 300a may set a balance mark indicating that the balancing of the codeword CW1 has failed (i.e., there is not zero disparity).

For example, the disparity control unit 300a may generate a balance parity BP in page units. A page is a unit of the programming operation and reading operation of the nonvolatile memory device 100. That is, source words SW1 corresponding to a specific page can be received, and thereafter the disparity control unit 300a can generate a balance parity BP corresponding to the received source words SW1. Subsequently, the received source words SW1 and the balance parity BP can be output as a codeword CW1.

For example, the disparity control unit 300a can calculate and maintain a Running Digital Sum (RDS). The disparity control unit 300a may set the balance parity BP in order for the RDS to be controlled to 0. As an example, when the RDS of pre-programmed codewords CW1 is 3, the disparity control unit 300a may generate a balance parity BP having a disparity of −3, although the disparity of the received source word SW1 is 0. That is, when the RDS of the pre-programmed codewords is 3 in this example, the disparity control unit 300a may set the balance parity BP at −3 so that the RDS may be 0.

For example, the disparity control unit 300a may calculate an RDS in page units. When the first codeword CW1 of a specific page is programmed, the disparity control unit 300a can calculate the RDS. The disparity control unit 300a may update the RDS until the last codeword CW1 of a specific page is programmed. The last codeword CW1 of a specific page can be programmed, and thereafter the disparity control unit 300a may reset the RDS.

For example, the disparity control unit 300a may calculate an RDS in word units. That is, the disparity control unit 300a may update the RDS until the Least Significant Page (LSP) to the Most Significant Page (MSP) corresponding to a specific word line are programmed.

For example, the disparity control unit 300a may calculate an RDS in memory block units. A memory block is a unit of the erasing operation of the nonvolatile memory device 100.

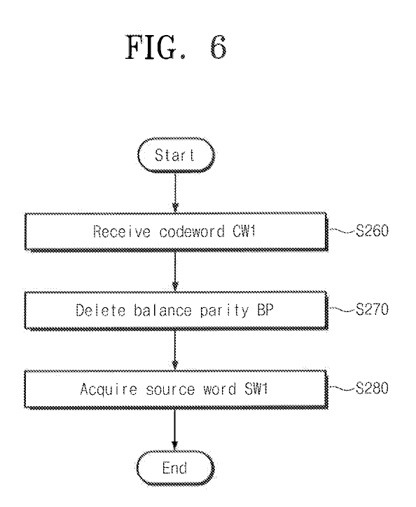

FIG. 6 is a flowchart illustrating an operation of the disparity control unit 300a of FIG. 4 in the reading operation of the nonvolatile memory device (e.g., nonvolatile memory device 100 illustrated in FIGS. 1 and 2).

Referring to FIGS. 4 and 6, a codeword CW1 is received in operation S260. For example, a codeword CW1 read from the nonvolatile memory device 100 may be received by the disparity control unit 300a. For example, the read code word CW1 may be received by the balance parity deleting unit 330a.

A balance parity BP can be deleted in operation S270. For example, the balance parity deleting unit 330a may delete the balance parity BP from the received codeword CW1. As an example, the length of the balance parity BP may be preset. Therefore, the balance parity deleting unit 330a may detect and delete the balance parity BP of the received codeword CW1. By deleting the balance parity BP, a source word SW1 can be obtained from the codeword CW1 in operation S280.

For example, the controller 100 may control the nonvolatile memory device 100 so that a source word SW1 may be read from the nonvolatile memory device 100 in a reading operation. The balance parity deleting unit 330a may not be provided to the parity control unit 300a.

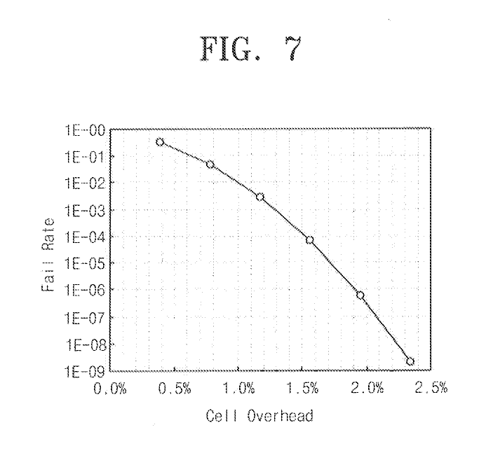

FIG. 7 is a graph illustrating the probability that a zero disparity may fail, based on the number of bits of codewords CW1 and a balance parity BP. In FIG. 7, the abscissa axis (e.g., the y-axis) can represent the rate of a balance parity BP to the number of bits of codewords, and the ordinate axis (x-axis) can represent the probability that a zero disparity may fail. For example, the rate of the numbers of bits of source words SW and a balance parity BP corresponding to one page can be set on the abscissa axis. As illustrated in FIG. 7, as the rate of the balance parity BP increases, the probability that a zero disparity may fail decreases.

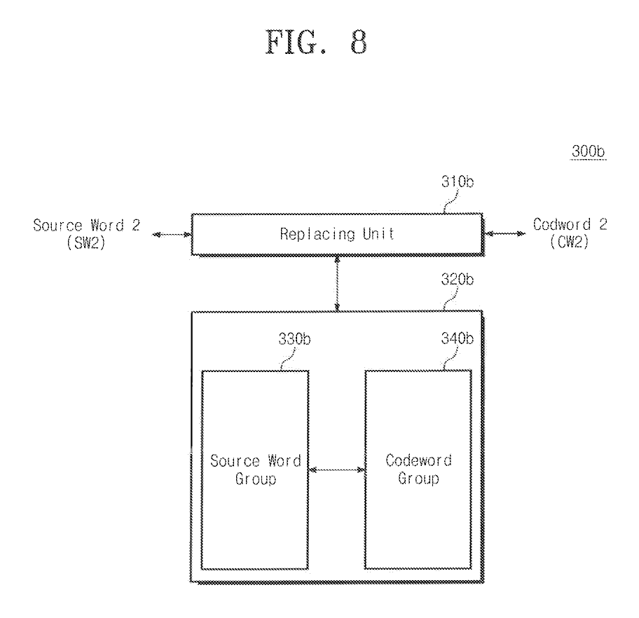

FIG. 8 is a block diagram illustrating a disparity control unit according to exemplary embodiments of the inventive concept.

Referring to FIG. 8, a disparity control unit according to exemplary embodiments of the present general inventive concept can include a replacing unit 310b and a replacing table 320b. The replacing table 320b can include a source word group 330b and a codeword group 340b.

The source word group 330b can include source words having a plurality of different patterns (e.g., source words of all patterns). The codeword group 340b can include codewords corresponding to the source words of the source word group 330b. Each of the codewords of the codeword group 340b can have a zero disparity. When the source word is configured with s bits, the number of patterns of the source word can be 2̂s. The codeword group 340b can include a 2̂s number of different zero disparity codewords. For configuring a 2̂s number of different zero disparity codewords, the bit number of each codeword of the codeword group 340b can be greater than the bit number of a source word.

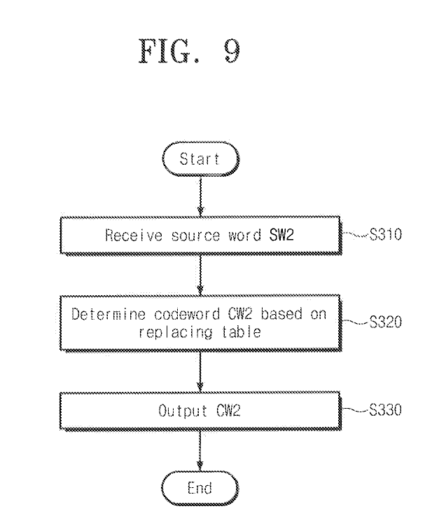

FIG. 9 is a flowchart illustrating an operation of the disparity control unit 300b of FIG. 8 according to exemplary embodiments of the present general inventive concept.

Referring to FIGS. 8 and 9, a source word SW2 can be received in operation S310. For example, the source word SW2 can be received by the replacing unit 310b from the host.

Based on the replacing table 310b, a codeword CW2 corresponding to the source word SW2 can be selected in operation S320. The replacing unit 310b can select the codeword CW2 corresponding to the received source word SW2 according to the replacing table 320b.

The selected codeword CW2 can be output in operation S330. For example, the selected codeword CW2 can be transferred to the nonvolatile memory device 100. Subsequently, the transferred codeword CW2 can be programmed in the nonvolatile memory device 100.

The codewords of the codeword group 340b may have a zero disparity. Therefore, the codeword CW2 transferred to the nonvolatile memory device 100 may also have a zero disparity. That is, a codeword CW2 having a zero disparity can be programmed in the nonvolatile memory device 100 irrespective of the pattern of the received source word SW2.

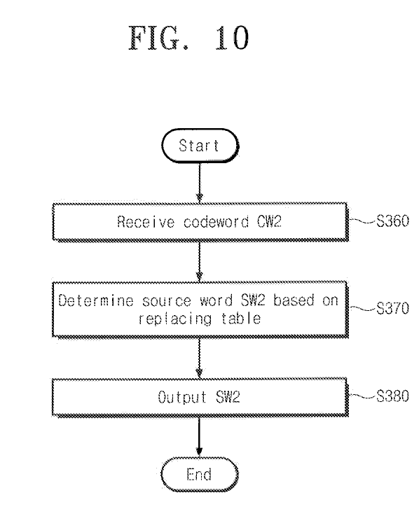

FIG. 10 is a flowchart illustrating an operation of the disparity control unit 300b of FIG. 8 in the reading operation of the nonvolatile memory device 100.

Referring to FIGS. 8 and 10, a codeword CW2 can be received in operation S360. For example, a codeword CW2 read from the nonvolatile memory device 100 can be transferred to the replacing unit 310b of the disparity control unit 300b.

The replacing unit 310b can determine a source word SW2 corresponding to the received codeword CW2 on the basis of the replacing table 320b in operation S370. The determined source word SW2 can be in operation S380. For example, the determined source word SW2 is transferred to a host.

As described above, the disparity control unit 300b can select a codeword CW2 that corresponds to the source word SW2 and has a zero disparity. Therefore, codewords CW2 programmed in the nonvolatile memory device 100 can have a zero disparity.

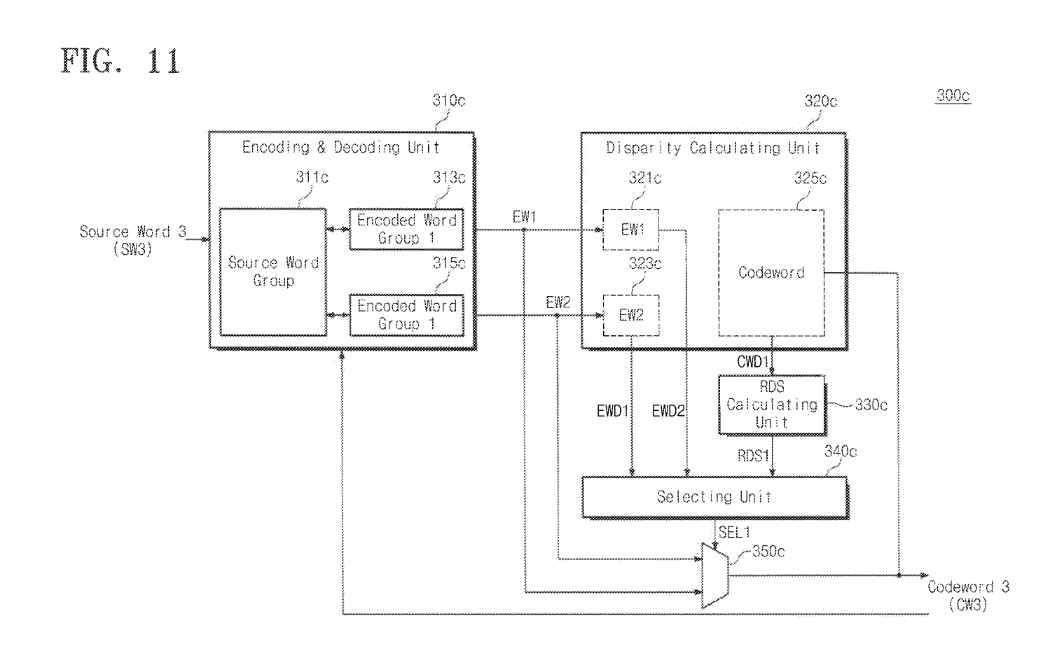

FIG. 11 is a block diagram illustrating a disparity control unit according to exemplary embodiments of the present general inventive concept.

Referring to FIG. 11, a disparity control unit 300c according to exemplary embodiments of the inventive concept can include an encoding and decoding unit 310c, a disparity calculating unit 320c, a Running Digital Sum (RDS) calculating unit 330c, a selecting unit 340c, and a multiplexer 350c.

The encoding and decoding unit 310c can include a source word group 311c, a first encoded word group 313c, and a second encoded word group 315c. The source word group 311c can include one or more of the patterns (e.g., all the patterns) of a source word.

The first encoded word group 313c can include first encoded words corresponding to one or more patterns (e.g., all patterns) of a source word. For example, encoded words can be set to have a disparity equal to or less than a reference value. The second encoded word group 315c can include second encoded words corresponding to one or more patterns (e.g., all patterns) of a source word. As an example, the first and second encoded words corresponding to a specific source word can be set to have disparities that have the same size and opposite signs, respectively.

The disparity calculating unit 320c can include a first encoded word calculator 321c, a second encoded word calculator 323c, and a codeword calculator 325c. The first and second encoded word calculators 321c and 323c can receive first and second encoded words EW1 and EW2 from the encoding and decoding unit 310c, respectively. The first and second encoded word calculators 321c and 323c can calculate the disparities of the first and second encoded words EW1 and EW2 received, respectively. First and second encoded word disparities EWD1 and EWD2 that are calculated can be transferred to the selecting unit 340c.

The codeword calculator 325c can receive and calculate a codeword CW3 outputted from the multiplexer 350c. The codeword calculator 325c can calculate the disparity of the received codeword CW3. A calculated codeword disparity CWD1 can be transferred to the RDS calculating unit 330c.

The RDS calculating unit 330c can calculate the RDS of codewords programmed in the nonvolatile memory device 100, based on the codeword disparity CWD1 received, with the RDS calculating unit having one or more circuits. For example, the RDS calculating unit 330c can calculate and maintain an RDS in page units, word line units, and/or memory block units. A calculated running digital sum RDS1 can be transferred to the selecting unit 340c.

The selecting unit 340c may have one or more logic circuits that can receive the first and second encoded word disparities EWD1 and EWD2 from the disparity calculating unit 320c. The selecting unit 340c can receive the running digital sum RDS1 from the RDS calculating unit 330c. The selecting unit 340c can generate a selection signal SEL1 with the one or more logic circuits based on the first and second encoded word disparities EWD1 and EWD2 and the running digital sum RDS1. The selection signal SEL1 can be transferred to the multiplexer 350c.

The multiplexer 350c can receive the first and second encoded words EW1 and EW2 from the encoding and decoding unit 310c. According to the selection signal SEL1, the multiplexer 350c can select one of the first and second encoded words EW1 and EW2 and outputs the selected word as a codeword CW3.

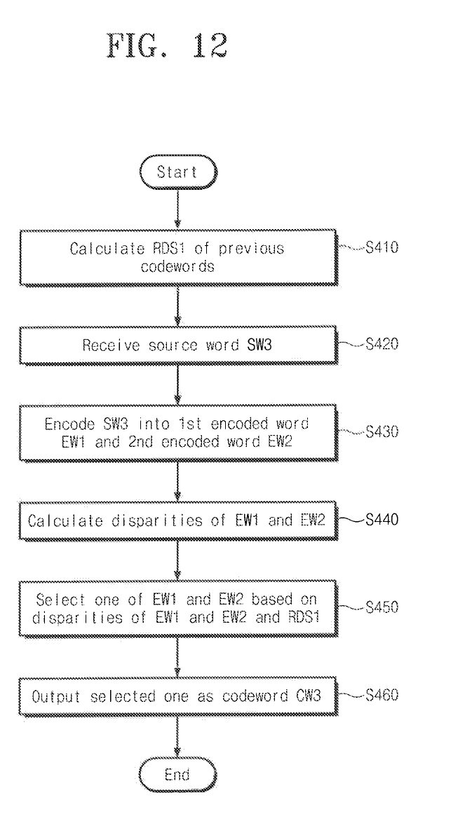

FIG. 12 is a flowchart illustrating an operation of the disparity control unit 300c of FIG. 11.

Referring to FIGS. 11 and 12, the running digital sum RDS1 of previous codewords can be calculated in operation S410. For example, the RDS calculating unit 330c may calculate the running digital sum of codewords programmed in the nonvolatile memory device 100. When a source word SW3 is received, the RDS calculating unit 330c can maintain the running digital sum RDS1 of codewords CW3 programmed in the nonvolatile memory device 100 before the source word SW3 is received in operation S420.

The source word SW can be encoded into first and second encoded words EW1 and EW2 in operation S430. The encoding and decoding unit 310c can select the first encoded word EW1 corresponding to a source word SW3 that is received from the first encoded word group 313c. The encoding and decoding unit 310c can select the second encoded word EW2 corresponding to a source word SW3 that is received from the second encoded word group 315c.

The disparities of the first and second encoded words EW1 and EW2 can be calculated in operation S440. For example, the disparity calculating unit 320c may calculate the disparities EWD1 and EWD2 of the first and second encoded words EW1 and EW2. For example, the first encoded word calculator 3210 may calculate the disparity EWD1 of the first encoded word EW1. The second encoded word calculator 323c may calculate the disparity EWD2 of the second encoded word EW2. The first and second encoded word disparities EWD1 and EWD2 may have the same size and different signs.

One of the first and second encoded words EW1 and EW2 can be selected, based on the disparities EWD1 and EWD2 of the first and second encoded words EW1 and EW2 and the running digital sum RDS1 in operation S450. For example, the selecting unit 340c can compare the running digital sum RDS1 and the disparities EWD1 and EWD2 of the first and second encoded words EW1 and EW2. The selecting unit 340c can select an encoded word having a disparity that decreases the absolute value of the running digital sum RDS1 among the first and second encoded words EW1 and EW2. For example, when the running digital sum RDS1 has a positive value, the selecting unit 340c can select an encoded word having a negative disparity. When the running digital sum RDS1 has a negative value, the selecting unit 340c can select an encoded word having a positive disparity.

The encoded word selected can be output as a codeword CW3 through the multiplexer 350c according to the control of the selecting unit 340c in operation S460. The disparity of the output codeword CW3 is reflected in the running digital sum RDS1 by the RDS calculating unit 330c. That is, the absolute value of the running digital sum RDS1 can decrease.

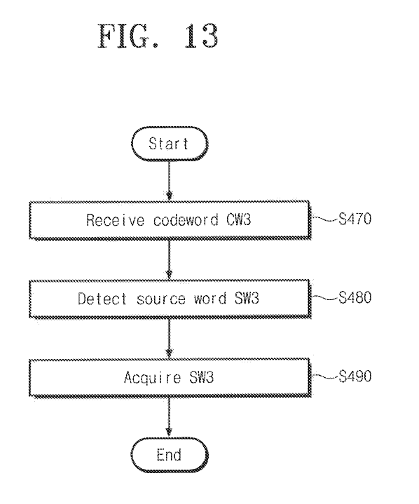

FIG. 13 is a flowchart illustrating an operation of the disparity control unit 300c of FIG. 11 in the reading operation of the nonvolatile memory device 100.

Referring to FIGS. 11 and 13, a codeword CW3 is received in operation S470. For example, a codeword CW3 read from the nonvolatile memory device 100 can be received by the disparity control unit 300c.

A source word SW3 can be detected in operation S480. For example, when a received codeword CW3 accords with one of the first encoded words of the first encoded word group 313c, the encoding and decoding unit 310c may select a source word SW3 corresponding to a first encoded word that accords with (e.g., is equal to and/or is the same as) the received codeword CW3. When the received codeword CW3 accords with one of the second encoded words of the second encoded word group 315c, the encoding and decoding unit 310c may select a source word SW3 corresponding to a second encoded word that accords with the received codeword CW3.

Based on the selection of the encoding and decoding unit 310c, a source word SW3 is acquired in operation S490.

As described above, the disparity control unit 300c can select a codeword CW3 that decreases the running digital sum RDS1. Therefore, codewords having total zero disparities or disparities close to zero can be programmed in the nonvolatile memory device 100.

In the above-described exemplary embodiments of the present general inventive concept, the disparity calculating unit 320c can include the first and second encoded word calculators 321c and 323c. The disparity calculating unit 320c may include only one of the first and second encoded word calculators 321c and 323c.

For example, the disparity calculating unit 320c may calculate the disparity EWD1 of the first encoded word EW1 through the first encoded word calculator 321c. The disparity EWD2 of the second encoded word EW2 and the disparity EWD1 of the first encoded word EW1 may have the same size and different signs. Accordingly, the second encoded word disparity EWD2 can be acquired from the first encoded word disparity EWD1.

For example, the first and second encoded word groups 313c and 315c may include encoded words and the disparities of the encoded words, respectively. In this case, the first and second encoded word calculators 321c and 323c may not be provided to the disparity calculating unit 320c.

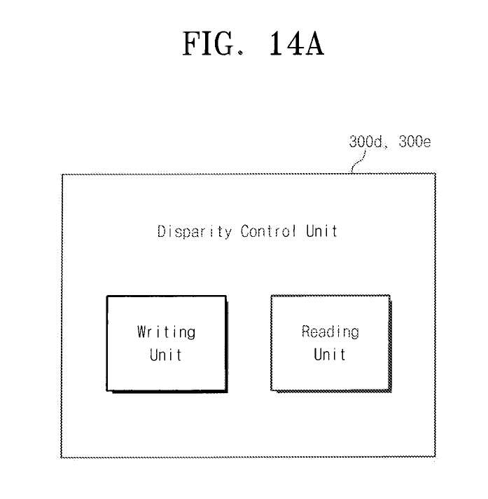

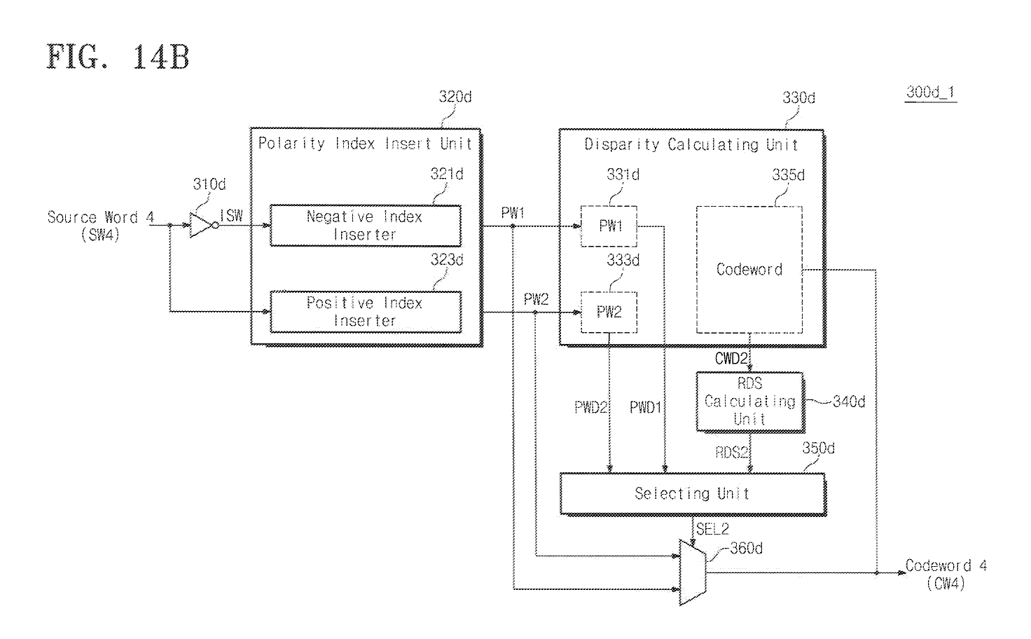

FIG. 14A is a block diagram illustrating a disparity control unit 300d according to exemplary embodiments of the present general inventive concept. The disparity control unit can include a writing unit and a reading unit. Exemplary embodiments of the disparity control unit 300d, as well as the writing unit and reading unit, are illustrated in FIGS. 14B-23 and are described below. The writing unit and the reading unit may include one or more logic circuits to control and/or perform one or more read operations and write operations, respectively.

FIG. 14B is a block diagram illustrating a writing unit 300d_1 of a disparity control unit 300d according to exemplary embodiments of the present general inventive concept.

Referring to FIG. 14B, a writing unit 300d_1 according to exemplary embodiments of the present general inventive concept can include an inverter 310d, a polarity index inserting unit 320d, a disparity calculating unit 330d, an RDS calculating unit 340d, a selecting unit 350d, and a multiplexer 360d.

The inverter 310d can receive a source word SW4 to generate an inverted source word ISW. The inverted source word ISW can be transferred to the polarity index inserting unit 320d.

The polarity index inserting unit 320d can receive the source word SW4 and the inverted source word ISW. The polarity index inserting unit 320d can insert a polarity index into the source word SW4 and the inverted source word ISW that are received. The polarity index inserting unit 320d can include a negative index inserter 321d and a positive index inserter 323d.

The negative index inserter 321d can insert a negative index into the inverted source word ISW. For example, the negative index inserter 321d may insert a first digital bit (for example, 1 or 0) into the inverted source word ISW. The polarized inverted source word ISW can configure a first polarity word PW1. The positive index inserter 323d can insert a positive index into the source word SW4. For example, the positive index inserter 323d may insert a second digital bit (for example, 1 or 0) into the source word SW4. The polarized source word SW4 can configure a second polarity word PW2. The first and second polarity words PW1 and PW2 can be transferred to the disparity calculating unit 330d.

The disparity calculating unit 330d can include a first polarity word calculator 331d, a second polarity calculator 333d, and a codeword calculator 335d. The first polarity word calculator 331d can calculate the disparity PWD1 of the first polarity word PW1. The second polarity word calculator 333d can calculate the disparity PWD2 of the second polarity word PW2. First and second polarity word disparities PWD1 and PWD2 can be transferred to the selecting unit 350d.

The codeword calculator 335d can calculate the disparity CWD2 of a codeword CW4 outputted from the multiplexer 360d. The codeword disparity CWD2 can be transferred to the RDS calculating unit 340d.

The RDS calculating unit 340d can calculate and maintain the running digital sum RDS2 of codewords programmed in the nonvolatile memory device 100, based on the codeword disparity CWD2 received. The calculated running digital sum RDS2 can be transferred to the selecting unit 350d.

The selecting unit 350d can generate a selection signal SEL2 based on the first and second polarity word disparities PWD1 and PWD2 and the running digital sum RDS2. The generated selection signal SEL2 can be transferred to the multiplexer 360d.

The multiplexer 360d can receive the first and second polarity words PW1 and PW2 from the polarity index inserting unit 320d. In response to the selection signal SEL2, the multiplexer 360d can output one of the first and second polarity words PW1 and PW2 as a codeword CW4.

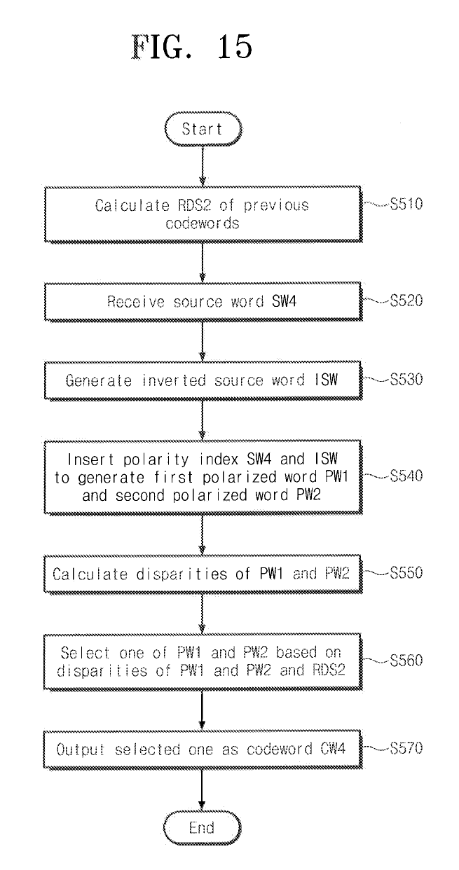

FIG. 15 is a flowchart illustrating an operation of the writing unit 300d_1 of FIG. 14B.

Referring to FIGS. 14B and 15, the running digital sum RDS2 of codewords CW4 that have been programmed previously can be calculated in operation S510. For example, the RDS calculating unit 340d may calculate and maintain the running digital sum RDS2 of codewords CW4 programmed in the nonvolatile memory device 100. When a source word SW4 is received, the RDS calculating unit 340d can maintain the running digital sum RDS2 of the codewords CW4 programmed in the nonvolatile memory device 100 before the source word SW4 is received in operation S520.

An inverted source word ISW can be generated in operation S530. For example, the inverter 310d may invert the source word SW4 to generate the inverted source word ISW.

A polarity index can be inserted into the source word SW and the inverted source word ISW, and first and second polarity words PW1 and PW2 can be generated in operation S540. For example, the negative index inserter 321d may insert a negative index into the inverted source word ISW. The positive index inserter 323d can insert a positive index into the source word SW4. The inverted source word ISW having an inserted polarity index can configure a first polarity word PW1, and the source word SW4 having an inserted polarity index can configure a second polarity word PW2.

The disparities of the first and second polarity words PW1 and PW2 can be calculated in operation 3550. For example, the first polarity word calculator 331d may calculate the disparity PWD1 of the first polarity word PW1. The second polarity word calculator 333d may calculate the disparity PWD2 of the second polarity word PW2. A negative index and a positive index can be inserted into the source word SW and the inverted source word ISW and thereby the first and second polarity words PW1 and PW2 can be generated. Therefore, the first and second polarity words PW1 and PW2 can have the same size and different signs.

The disparities PWD1 and PWD2 of the first and second polarity words PW1 and PW2 can be calculated in operation S560, and based on the running digital sum RDS2, one of the first and second polarity words PW1 and PW2 can be selected.

For example, the selecting unit 350d can compare the running digital sum RDS2 with the disparities PWD1 and PWD2 of the first and second polarity words PW1 and PW2. The selecting unit 350d can select an encoded word having a disparity that decreases the absolute value of the running digital sum RDS2 among the first and second polarity words PW1 and PW2. For example, when the running digital sum RDS2 has a positive value, the selecting unit 350d may select a polarity word having a negative disparity. When the running digital sum RDS2 has a negative value, the selecting unit 350d may select a polarity word having a positive disparity.

The selected polarity word can be outputted as a codeword CW4 through the multiplexer 360d according to the control of the selecting unit 350d in operation S570. The disparity of the output codeword CW4 can be reflected in the running digital sum RDS2 by the RDS calculating unit 340d. That is, the absolute value of the running digital sum RDS2 can be reduced.

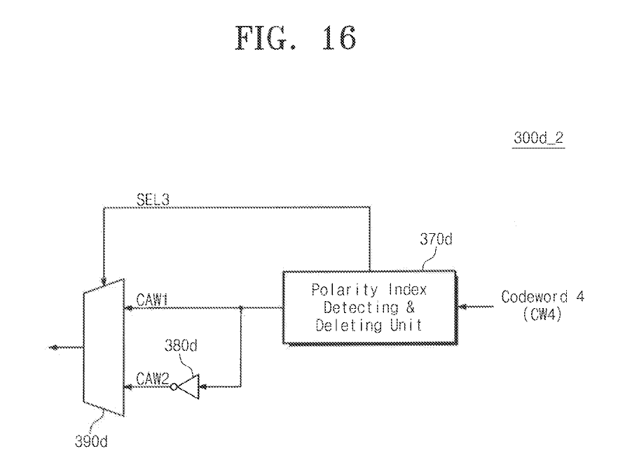

FIG. 16 is a block diagram illustrating a reading unit 300d_2 of a disparity control unit 300d illustrated in FIG. 14A according to exemplary embodiments of the present general inventive concept.

Referring to FIG. 16, a reading unit 300d_2 according to exemplary embodiments of the present general inventive concept can include a polarity index detecting and deleting unit 370d, an inverter 380d, and a multiplexer 390d.

The polarity index detecting and deleting unit 370d can receive a codeword CW4. The polarity index detecting and deleting unit 370d can generate a selection signal SEL3. A codeword, from which a polarity index has been removed, can be transferred to the multiplexer 390d as a first candidate word CAW1. A codeword, from which a polarity index has been removed, can be transferred to the inverter 380d. The inverter 380d can invert the codeword from which the polarity index has been removed and can transfer the inverted codeword as a second candidate word CAW2 to the multiplexer 390d.

The multiplexer 390d can output one the first and second candidate words CAW1 and CAW2 as a source word SW4 in response to the selection signal SEL3.

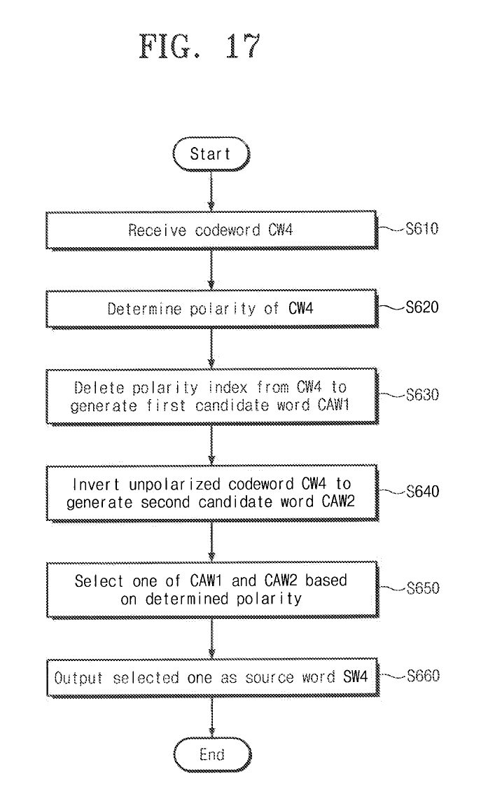

FIG. 17 is a flowchart illustrating an operation of the reading unit 300d2 of FIG. 16,

Referring to FIGS. 16 and 17, a codeword CW4 can be received in operation S610. For example, a codeword CW4 read from the nonvolatile memory device 100 may be received by the reading unit 300d_2.

The polarity of the codeword CW4 can be determined in operation S620. The polarity index detecting and deleting unit 370d can detect and determine a polarity index from the received codeword CW4. For example, a polarity index may be inserted into a specific location. Therefore, the polarity index detecting and deleting unit 370d may detect a polarity index from the received codeword CW4.

The polarity index can be deleted from the received codeword CW4 in operation S630. A codeword, from which the polarity index has been removed, can configure a first candidate word CAW1. For example, the polarity index detecting and deleting unit 370d can delete the polarity index from the received codeword CW4 to output it as the first candidate word CAW1.

The codeword, from which the polarity index has been removed, can be inverted in operation S640. The codeword, from which the polarity index has been removed, can be inverted to configure the second candidate word CAW2. For example, the polarity index detecting and deleting unit 370d may transfer the codeword, from which the polarity index has been removed, to the inverter 380d. The output of the inverter 380d may configure the second candidate word CAW2.

Based on the determined polarity, one of the first and second candidate words CAW1 and CAW2 can be selected in operation S650. For example, when the detected polarity index has a positive polarity, the polarity index detecting and deleting unit 370d may select the first candidate word CAW1. When the detected polarity index has a negative polarity, the polarity index detecting and deleting unit 370d may select the second candidate word CAW2.

A selected candidate word can be output as a source word SW4 according to the control of the polarity index detecting and deleting unit 370d in operation S660. When a polarity index is inserted into the source word SW4 and programmed in the nonvolatile memory device 100, a first candidate word CAW1 where a polarity index has been removed from a read codeword CW4 can be selected as the source word SW4. A second candidate word CAW2, where a codeword from which a polarity index has been removed is inverted, can be selected as the source word SW4 when a polarity index is inserted into an inverted source word ISW and programmed in the nonvolatile memory device 100.

As described above, the disparity control unit 300d can select a codeword CW4 that decreases a running digital sum RDS2. Therefore, codewords having all zero disparities or disparities close to zero can be programmed in the nonvolatile memory device 100.

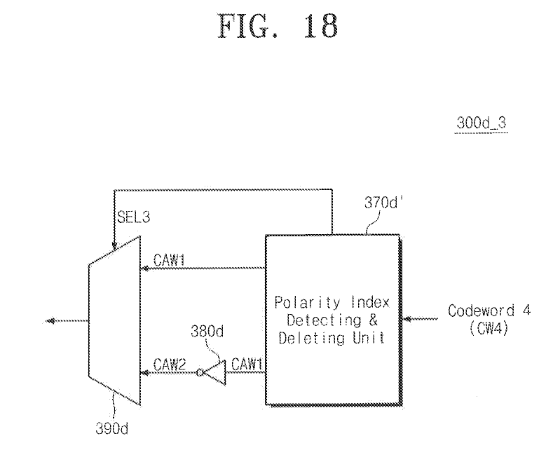

FIG. 18 is a block diagram illustrating a reading unit 300d_3 of a disparity control unit 300d according to exemplary embodiments of the present general inventive concept.

Referring to FIG. 18, a reading unit 300d_3 according to exemplary embodiments of the present general inventive concept can include a polarity index detecting and deleting unit 370d′, an inverter 380d, and a multiplexer 390d.

The polarity index detecting and deleting unit 370d′ can receive a codeword CW4. The polarity index detecting and deleting unit 370d′ can detect and delete a polarity index from the received codeword CW4. Based on the detected polarity index, the polarity index detecting and deleting unit 370d′ can control a selection signal SEL3. Based on the detected polarity index, the polarity index detecting and deleting unit 370d′ can output a codeword CAW1, from which a polarity index has been removed, to the multiplexer 390d or the inverter 380d. The output of the inverter 380d can be transferred to the multiplexer 390d.

The multiplexer 390d can output either the output of the polarity index detecting and deleting unit 370d′ or the output of the inverter 380d as a source word SW4 in response to the selection signal SEL3.

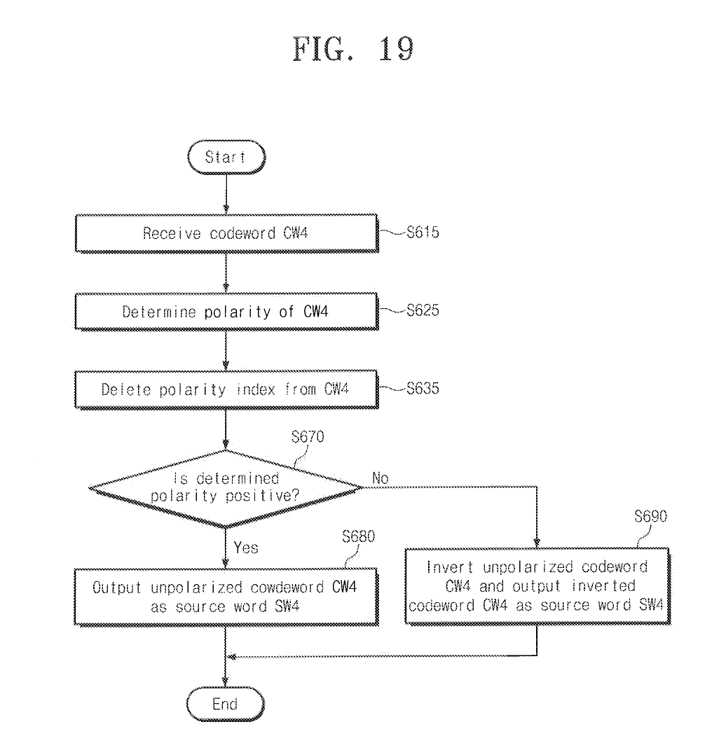

FIG. 19 is a flowchart illustrating an operation of the reading unit 300d_3 of FIG. 18.

Referring to FIGS. 18 and 19, the reading unit 300d_3 can receive a codeword CW4 in operation S615. The reading unit 300d_3 can determine the polarity of the received codeword CW4 in operation S625. For example, the polarity index detecting and deleting unit 370d′ may determine the polarity of the received codeword CW4.

The reading unit 300d_3 can delete a polarity index from the received codeword CW4 in operation S635. For example, the polarity index detecting and deleting unit 370d′ may delete a polarity index from the received codeword CW4.

The reading unit 300d_3 can determine whether the determined polarity is positive in operation S670. When the determined polarity is positive, the reading unit 300d_3 can output a codeword CAW1, from which a polarity index has been removed, as a source word SW4 in operation S680. For example, the polarity index detecting and deleting unit 370d′ can output a codeword CAW1, from which a polarity index has been removed, to the multiplexer 390d and can control the selection signal SEL3 so as to select the codeword CAW1 from which the polarity index has been removed.

When the determined polarity is not positive, the reading unit 300d_3 can invert the codeword CAW1 from which the polarity index has been removed and can output an inverted codeword CAW2 as a source word SW4 in operation S690. For example, the polarity index detecting and deleting unit 370d′ can output a codeword CAW1, from which a polarity index has been removed, to the inverter 380d and can control the selection signal SEL3 so as to select the output of the inverter 380d.

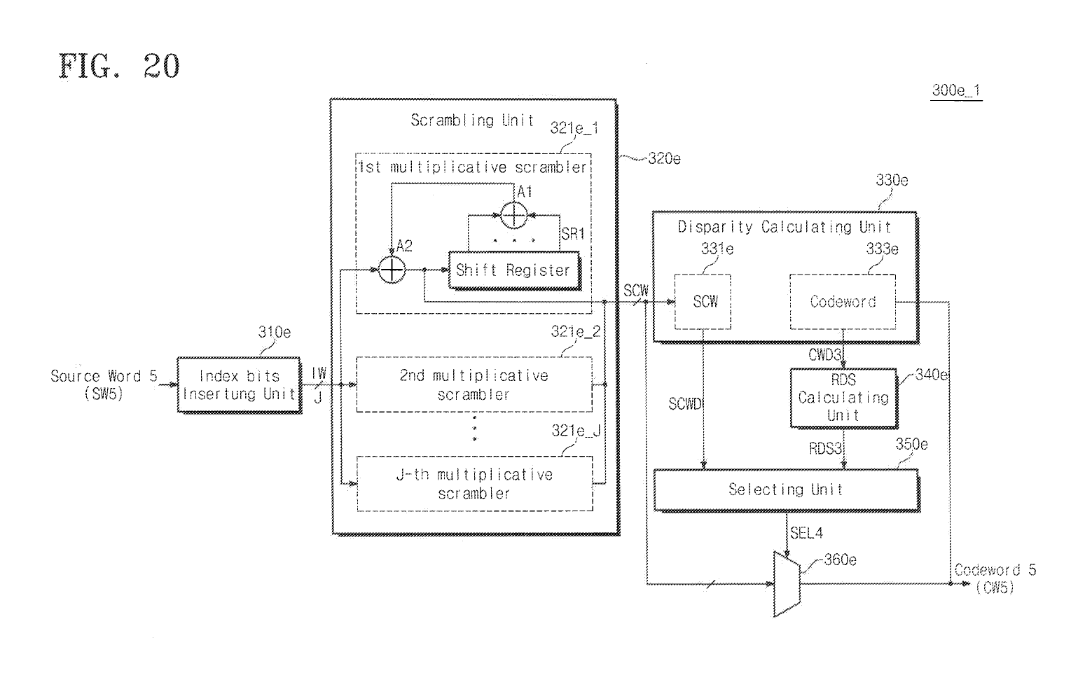

FIG. 20 is a block diagram illustrating a writing unit 300e_1 of a disparity control unit 300e illustrated in FIG. 14A according to exemplary embodiments of the present general inventive concept.

Referring to FIG. 20, a writing unit 300e_1 according to exemplary embodiments of the present general inventive concept can include an index bit inserting unit 310e, a scrambling unit 320e, a disparity calculating unit 330e, an RDS calculating unit 340e, a selecting unit 350e, and a multiplexer 360e.

The index bit inserting unit 310e can insert index bits into the source word SW5. The index bit inserting unit 310e can insert index bits into the source word SW5 to generate a plurality of index words IW. For example, it can be assumed that the index bit inserting unit 310e inserts a p-bit index bit. The index bit inserting unit 310e may generate one or more patterns (e.g., all patterns) that may be generated by p bits. That is, the index bit inserting unit 310e may generate 2̂p or less patterns. The index bit inserting unit 310e may insert the generated 2̂p or less patterns into a source word SW5 to generate 2̂p or less index words IW. For example, it can be assumed that the index bit inserting unit 310e generates a J number of index words IW. The generated index words (equal to or less than 2̂p) can be transferred to the scrambling unit 320e.

The scrambling unit 320e can include a plurality of scramblers 321e_1 to 321e_J. One or more of the scramblers 321e_1 to 321e_J may include one or more adder circuits and shift registers to scramble the received index word IW (i.e., to form one or more scrambled words SCW) according to the exemplary embodiments of the present general inventive concept as disclosed herein. For example, the scrambling unit 320e can include a plurality of multiplicative scramblers 321e_1 to 321e_J. The number of the scramblers 321e_1 to 321e_J may be proportional to the number of index words IW that are received from the index bit inserting unit 310e. That is, there may be a predetermined ratio of the number of the scramblers 321e1 to 321e_J to the number of index words IW. A J number of index words IW can be transferred to the multiplicative scramblers 321e_1 to 321e_J, respectively. Each of the multiplicative scramblers can perform multiplicative scrambling on the received index word IW.

Respective multiplicative scramblers can be identically configured. For example, each of the multiplicative scramblers can include a first adder A1, a second adder A2, and a shift register SR1. The first and second bits of the shift register SR1 can be summed by the first adder A1. For example, at least two bits of the shift register SR1 may be summed by the first adder A1. The output of the first adder A1 and an index word IW can be summed by the second adder A2. The output of the second adder A2 can configure a scrambled word SCW. At this point, the adder may perform an XOR operation.

The J output words of the scrambling unit 320e can configure scrambled words SCW. The J scrambled words SCW can be transferred to the disparity calculating unit 330e.

The disparity calculating unit 330e can include a scrambled word calculator 331e and a codeword calculator 333e. The disparity calculating unit 330e can calculate the respective disparities SCWD of the J scrambled words SCW. The scrambled word disparity SCWD that is calculated can be transferred to the selecting unit 350e. The codeword calculator 333e can calculate the disparity CWD3 of a codeword CW5 that is output from the multiplexer 360e. The calculated codeword disparity CWD3 can be transferred to the RDS calculating unit 340e.

The RDS calculating unit 340e can calculate the running digital sum RDS3 of codewords CW4 programmed in the nonvolatile memory device 100. The calculated running digital sum RDS3 can be transferred to the selecting unit 350e.

The selecting unit 350e can compare the received running digital sum RDS3 and the scrambled word disparities SCWD. The selecting unit 350e can control a selection signal SEL4 according to the compared result.

The multiplexer 360e can receive a J number of scrambled words SCW from the scrambling unit 320e. In response to the selection signal SEL4, the multiplexer 360e can output one of the J scrambled words SCW as a codeword CW5.

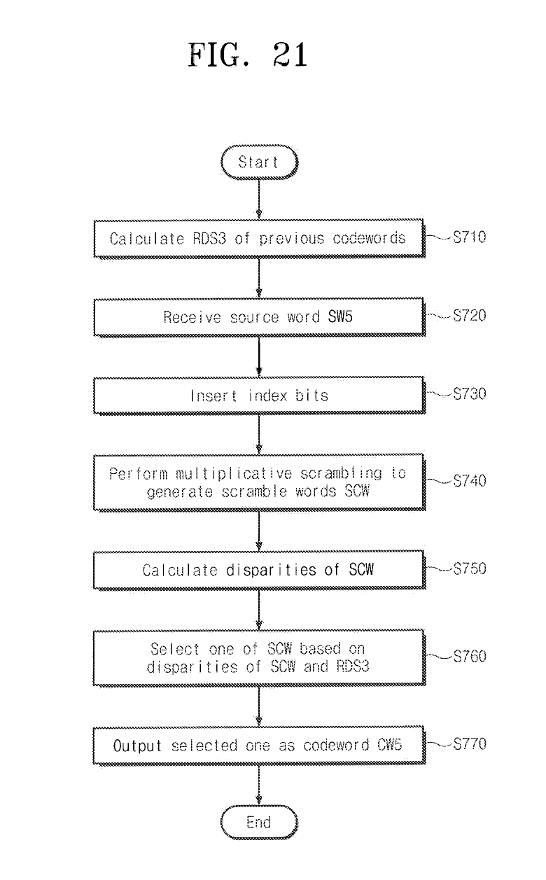

FIG. 21 is a flowchart illustrating an operation of the writing unit 300e_1 of FIG. 20.

Referring to FIGS. 20 and 21, the running digital sum RDS3 of previous codewords CW5 can be calculated. For example, the RDS calculating unit 340e can calculate and maintain the running digital sum RDS3 of codewords CW5 programmed in the nonvolatile memory device 100. When a source word SW5 is received, the RDS calculating unit 340e can maintain the running digital sum RDS3 of the codewords programmed in the nonvolatile memory device 100 before the source word SW5 is received in operation S720.

An index bit can be inserted in operation S730. For example, the index bit inserting unit 310e can insert a J number of indexes having different patterns into the source word SW5 to generate a J number of index words IW.

Multiplicative scrambling can be performed in operation S740. For example, the scrambling unit 320e can perform multiplicative scrambling on the J index words IW to generate a J number of scrambled words SCW. Since the index portions of the index words IW differ, the scrambled words SCW can also differ.

The disparities SCWD of the scrambled words SCW can be calculated in operation S750. For example, the scrambled word calculator 331e may calculate the disparities SCWD of the J scrambled words SCW, respectively. Since the scrambled words SCW can differ, the scrambled word disparities SCWD may have various values.

Based on the disparities SCWD of the scrambled words SCW and the running digital sum RDS3, one of the scrambled words SCW can be selected in operation S760. For example, the selecting unit 350e can compare the disparities SCWD of the scrambled words SCW and the running digital sum RDS3. The selecting unit 350e may select a scrambled word having a disparity that decreases the absolute value of the running digital sum RDS3 among the scrambled words SCW. For example, when the running digital sum RDS3 has a positive value, the selecting unit 350e may select a polarity word having a negative disparity. When the running digital sum RDS3 has a negative value, the selecting unit 350e may select a polarity word having a positive disparity.

The scrambled word selected can be output as a codeword CW5 through the multiplexer 360e according to the control of the selecting unit 350e in operation S770. The disparity of the output codeword CW5 can be included in the running digital sum RDS3 by the RDS calculating unit 340e. That is, the absolute value of the running digital sum RDS3 can be reduced.

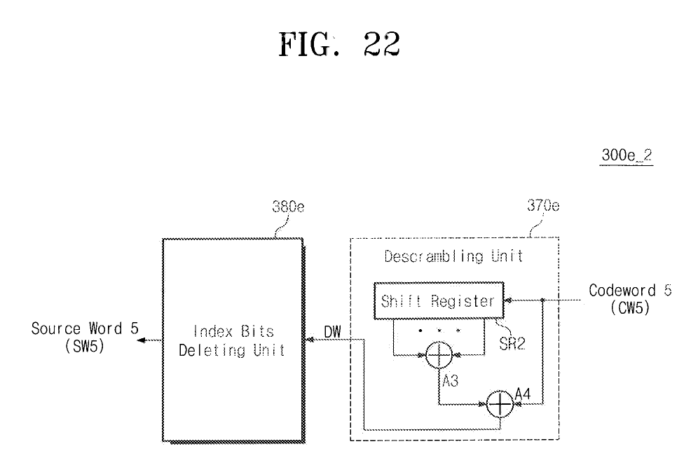

FIG. 22 is a block diagram illustrating a reading unit 300e_2 of a disparity control unit 300e according to exemplary embodiments of the present general inventive concept.

Referring to FIG. 22, a reading unit 300e_2 according to exemplary embodiments of the present general inventive concept can include a descrambling unit 370e and an index bit deleting unit 380e.

The descrambling unit 370e can perform multiplicative descrambling on a codeword CW5. For example, the descrambling unit 370e can include a shift register SR2, a third adder A3, and a fourth adder A4. The first and second bits of the shift register SR2 can be summed by the third adder A3. For example, at least two bits of the shift register SR2 may be summed by the third adder A3. The output of the third adder A3 and a codeword CW5 can be summed by the fourth adder A4. The output of the fourth adder A4 can be transferred as a descrambled word SCW to the index bit deleting unit 380e.

The index bit deleting unit 380e can receive a descrambled word DW. The index bit deleting unit 380e can delete an index bit from the descrambled word DW. The output of the index bit deleting unit 380e can be output as a source word SW5.

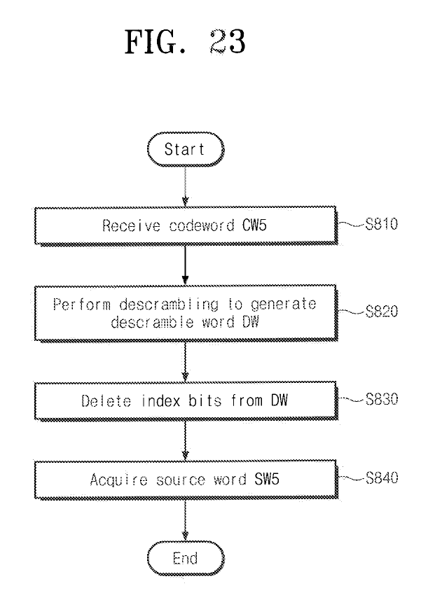

FIG. 23 is a flowchart illustrating an operation of the reading unit 300e_2 of FIG. 22.

Referring to FIGS. 22 and 23, a codeword CW5 can be received in operation S810. For example, the codeword CW5 read from the nonvolatile memory device 100 can be received by the reading unit 300e_2.

Descrambling can be performed in operation S820. For example, the descrambling unit 370e can descramble the received codeword CW5. The descrambled result can configure a descrambled word DW.

An index bit can be deleted from the descrambled word DW in operation S830. For example, the index bit deleting unit 380e may delete an index bit from the descrambled word DW received. A source word SW5 can be acquired by the deletion of the index bit in operation S840.

As described above, the disparity control unit 300e can select a codeword CW5 that decreases the running digital sum RDS3. Therefore, codewords having all zero disparities or disparities close to zero can be programmed in the nonvolatile memory device 100.

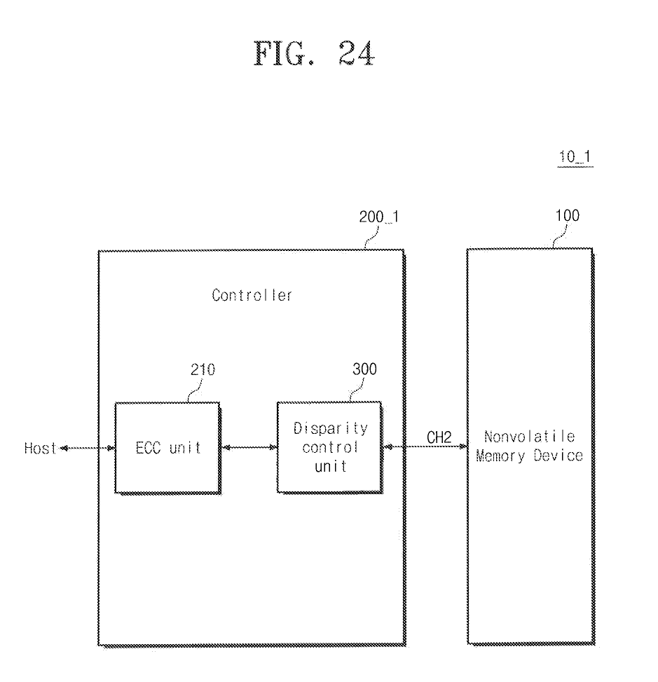

FIG. 24 is a block diagram illustrating an example of the memory system 10 of FIG. 1.

Referring to FIG. 24, a memory system 10_1 can include a nonvolatile memory device 100 and a controller 200_1. The nonvolatile memory device 100 and the controller 200_1 may be communicatively coupled to one another via a channel (e.g., CH2 as illustrated in FIG. 24). The controller 200_1 can include an error correction (ECC) unit 210 and a disparity control unit 300.

The nonvolatile memory device 100 may be the same as described above with reference to FIGS. 1 and 2.

The disparity control unit 300 may be the same as described above with reference to FIGS. 3 to 23.

The error correction unit 210 may have one or more logic circuits to correct errors and can include an Error Correction Code (ECC). For example, the error correction unit 210 may generate a first parity based on data to be written in the nonvolatile memory device 100. The generated parity may be written in the nonvolatile memory device 100 together with a writing data. The error correction unit 210 may generate a second parity based on a read data that is read from the nonvolatile memory device 100. The error correction unit 210 may correct the error of the read data, based on the first parity read from the nonvolatile memory device 100 and the generated second parity.

For example, data received from a host can be transferred to the disparity control unit 300 through the error correction unit 210. That is, the number of parities generated by the error correction unit 210 and the number of writing data may be standardized.

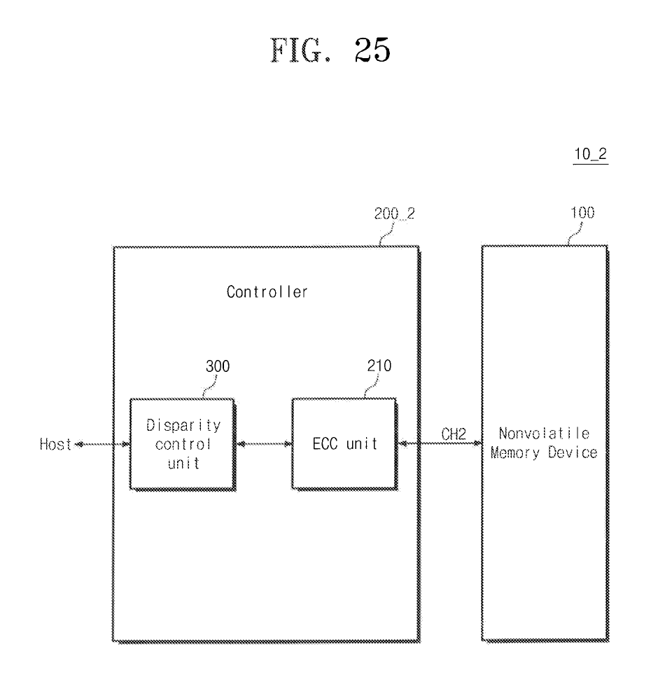

FIG. 25 is a block diagram illustrating another example of the memory system 10 of FIG. 1

Referring to FIG. 25, a memory system 10_2 includes a nonvolatile memory device 100 and a controller 200_2. The nonvolatile memory device 100 and the controller 200_1 may be communicatively coupled to one another via a channel (e.g., CH2 as illustrated in FIG. 25).

Except for that data received from a host is transferred to an error correction (ECC) unit 210 through a disparity control unit 300 and data read from the nonvolatile memory device 100 is transferred to the disparity control unit 300 through the error correction unit 210, the memory system 10_2 may be the same as the memory system 10_1 that has been described above with reference to FIG. 24.

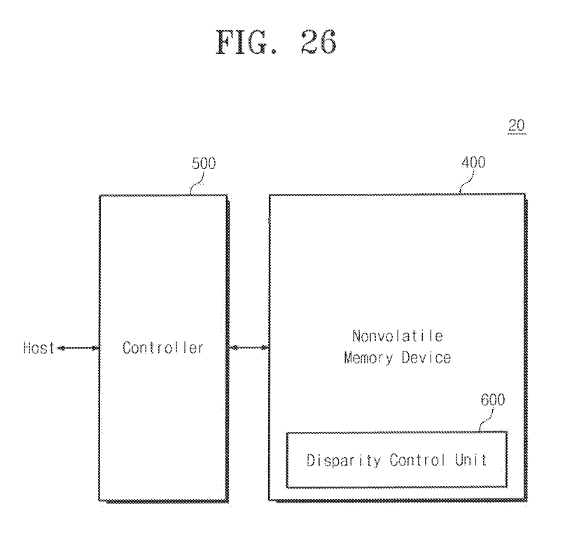

FIG. 26 is a block diagram illustrating a memory system 20 according to exemplary embodiments of the present general inventive concept.

Referring to FIG. 26, a memory system 20 according to exemplary embodiments of the present general inventive concept can include a nonvolatile memory device 400 and a controller 500.

Except for that a disparity control unit 600 can be provided to the nonvolatile memory device 400, the memory system 20 can be the same as the memory system 10 of FIG. 1. The disparity control unit 600 can convert a source word SW, which can be received from the controller 500, to a codeword CW. The disparity control unit 600 may operate as described above with reference to FIGS. 3 to 23.

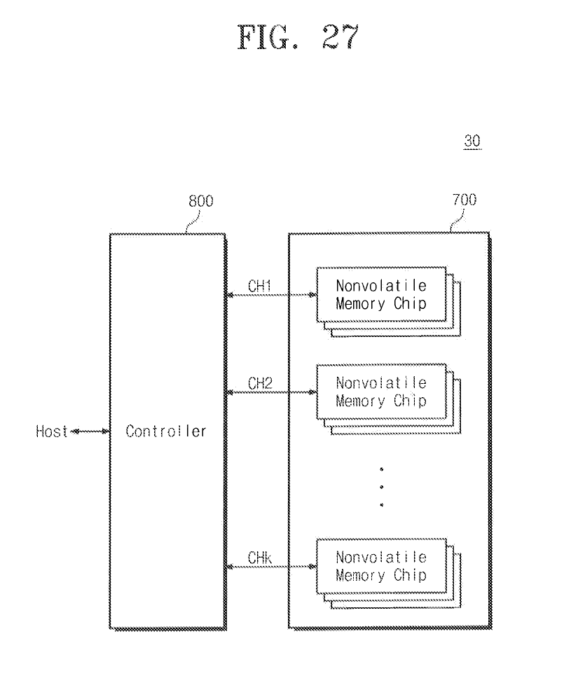

FIG. 27 is a block diagram illustrating a memory system 30 according to exemplary embodiments of the present general inventive concept.

Referring to FIG. 27, a memory system 30 according to exemplary embodiments of the present general inventive concept includes a nonvolatile memory device 700 and a controller 800. The nonvolatile memory device 700 can include a plurality of nonvolatile memory chips. The plurality of nonvolatile memory chips can be divided into a plurality of groups. Each group of the nonvolatile memory chips can communicate with the controller 800 though one common channel. In FIG. 27, it is illustrated that the plurality of nonvolatile memory chips communicate with the controller 800 through first to kth channels CH1 to CHk.

For example, as described above with reference to FIG. 1, the controller 800 may include a disparity control unit 300. For example, as described above with reference to FIG. 26, each of the nonvolatile memory chips may include a disparity control unit 300.

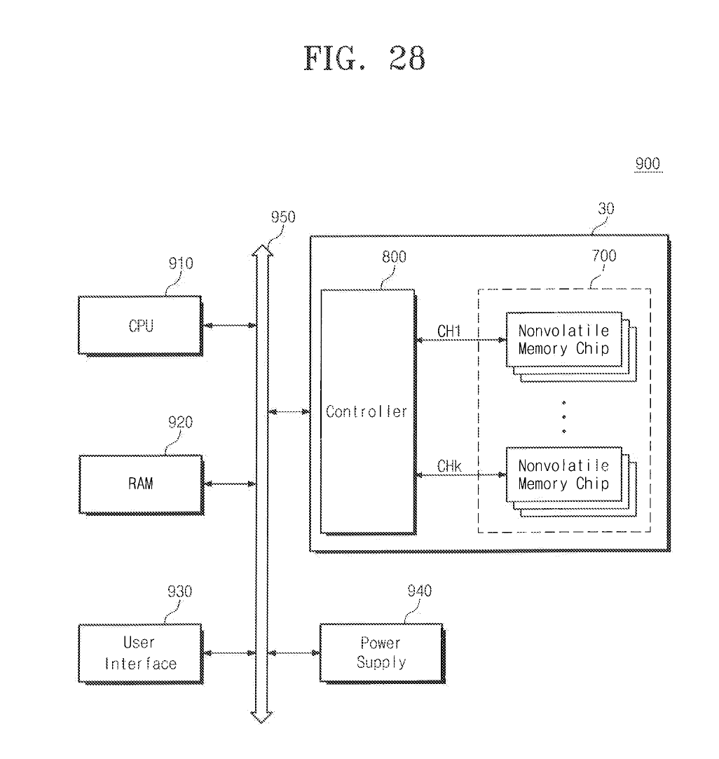

FIG. 28 is a block diagram illustrating a computing system 900 according to exemplary embodiments of the present general inventive concept which includes the memory system 30 which has been described above with reference to FIG. 27.

Referring to FIG. 28, a computing system 900 can include a Central Processing Unit (CPU) 910, a Random Access Memory (RAM) 920, a user interface 930, a power supply 940, and a memory system 30.

The memory system 30 can be electrically connected to the CPU 910, the RAM 920, the user interface 930, and the power supply 940 through a system bus 950. Data processed by the CPU 930 can be stored in the memory system 30. The memory system 30 can include the controller 800 and the nonvolatile memory device 700.

In FIG. 28, it is illustrated that the nonvolatile memory device 700 can be connected to the system bus 950 through the controller 800. However, the nonvolatile memory device 700 may be directly connected to the system bus 950.

In FIG. 28, it is illustrated that the computing system 900 may include the memory system 30 illustrated in FIG. 27. However, the memory system 30 may be replaced with the memory system 10, 10_1, 10_2 or 20 that have been respectively described above with reference to FIG. 1, 24, 25 or 26.

According to exemplary embodiments of the present general inventive concept, the source word can be converted into the code word having a standardized number of the first and second digital bits. Accordingly, the nonvolatile memory device, the controller, and the memory system including the same may have increased and/or improved reliability.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

1. A method of operating a memory system including a nonvolatile memory device and a controller, the method comprising:
receiving a source word;
converting the received source word to a codeword; and
programming the converted codeword in the nonvolatile memory device,
wherein:
a length of the converted codeword is greater than a length of the received source word, and
a difference between the numbers of first and second digital bits of the converted codeword is less than a reference value.

2. The method of claim 1, wherein the numbers of first and second digital bits of the converted codeword have predetermined values in the converting of the received source word.

3. The method of claim 1, wherein the converting the received source word comprises:
calculating a difference between the numbers of first and second digital bits of the received source word;
generating a balance parity based on the calculated difference; and
selecting the received source word and the balance parity as the converted codeword.

4. The method of claim 3, wherein the balance parity compensates the difference between the number of first digital bits and the number of second digital bits.

5. The method of claim 3, further comprising:
reading the programmed codeword in a reading operation; and
removing the balance parity of the read codeword to acquire the source word from the read codeword.

6. The method of claim 1, wherein the converting the received source word comprises:
selecting a codeword corresponding to the received source word, based on a specific replacing table which comprises a group of source words and a group of codewords.

7. The method of claim 6, wherein the numbers of first and second digital bits of each of the codewords have predetermined values.

8. The method of claim 6, further comprising:
reading the programmed codeword in a reading operation; and
selecting a source word corresponding to the read codeword based on the replacing table.

9. The method of claim 1, further comprising:
calculating a sum of differences between the numbers of first and second digital bits of codewords which are pre-converted before the converting of the received source word.

10. The method of claim 9, wherein the converting the received source word comprises:
selecting first and second encoded words corresponding to the received source word, based on a replacing table comprising a group of source words, a group of first encoded words, and a group of second encoded words;
calculating a difference between the numbers of first and second digital bits of the selected first encoded words, and a difference between the numbers of first and second digital bits of the selected second encoded words; and
selecting one of the selected first and second encoded words as a codeword, based on the sum of differences between the numbers of first and second digital bits of the pre-converted codewords, the difference between the numbers of first and second digital bits of the selected first encoded words, and the difference between the numbers of first and second digital bits of the selected second encoded words.

11. The method of claim 10, wherein the difference between the numbers of first and second digital bits of the selected first encoded words and the difference between the numbers of first and second digital bits of the selected second encoded words have the same size and different signs.

12. The method of claim 10, wherein the selecting of one of the selected first and second encoded words as a codeword comprises:
decreasing an absolute value of a sum of differences between the numbers of first and second digital bits of the pre-converted codewords among the first and second encoded words.

13. The method of claim 10, further comprising:
reading the programmed codeword in a reading operation; and
selecting a source word corresponding to the read codeword based on the replacing table.

14. The method of claim 9, wherein the converting the received source word comprises:
generating an inverted word of the received source word;
respectively inserting polarity bits into the received source word and the inverted word to polarize the words;
calculating a difference between the numbers of first and second digital bits of the polarized source word and a difference between the numbers of first and second digital bits of the polarized inverted word; and
selecting one of the polarized source word and the polarized inverted word as a codeword, based on the sum of differences between the numbers of first and second digital bits of the pre-converted codewords, the difference between the numbers of first and second digital bits of the polarized source word, and the difference between the numbers of first and second digital bits of the polarized inverted word.

15. The method of claim 14, further comprising:
reading the programmed codeword in a reading operation;
detecting a polarity bit from the read codeword;
removing the polarity bit from the read codeword; and
selecting whether to invert a codeword from which the polarity bit is removed based on the detected polarity bit.

16. The method of claim 9, wherein the converting the received source word comprises:
inserting different J-bit index bits into the received source word to generate less than or equal to 2̂J number of index words;
scrambling the less than or equal to 2̂J index words to generate less than or equal to 2̂J number of scrambled words;
calculating a difference between the numbers of first and second digital bits of each of the less than or equal to J scrambled words; and
selecting one of the less than or equal to 2̂J scrambled words as a codeword, based on the sum of differences between the numbers of first and second digital bits of the pre-converted codewords and the difference between the numbers of first and second digital bits of each of the less than or equal to 2̂J scrambled words.

17. The method of claim 16, wherein the generating of the less than or equal to 2̂J number of scrambled words comprises multiplicative scrambling the less than or equal to 2̂J scrambled index words.

18. The method of claim 1, wherein the converting the received source word comprises:
inserting different J-bit index bits into the received source word to generate less than or equal to 2̂J number of index words;
scrambling the less than or equal to 2̂J index words to generate less than or equal to 2̂J number of scrambled words;
calculating a difference between the numbers of first and second digital bits of each of the less than or equal to 2̂J scrambled words; and
selecting one of the less than or equal to 2̂J scrambled words as a codeword based on the calculation result.

19. A method of operating a controller to control a nonvolatile memory device in a memory system, the method comprising:
receiving a source word;
converting the received source word to a codeword; and
outputting the converted codeword to the nonvolatile memory device,
wherein:
a length of the converted codeword is greater than a length of the received source word, and
a difference between the numbers of first and second digital bits of the converted codeword is less than a reference value.

20. A method of operating a nonvolatile memory device in a memory system, the method comprising:
receiving a source word;
converting the received source word to a codeword; and
programming the converted codeword,
wherein:
a length of the converted codeword is greater than a length of the received source word, and
a difference between the numbers of first and second digital bits of the converted codeword is less than a reference value.
